(19) United States
(12) Patent Application Publication
(10) Pub. No.: US 2004/0086807 A1
(43) Pub. Date: May 6, 2004

(54) Method of fabricating thin film transistor

(76) Inventors: Chih-Yu Peng, Hsinchu (TW); Yen-Wen Fang, Miaolihsien (TW)

Correspondence Address: KNOBBE MARTENS OLSON & BEAR LLP, 2040 MAIN STREET, FOURTEENTH FLOOR, IRVINE, CA, 92614, US

(21) Appl. No.: 10/289,468

(22) Filed: Nov. 6, 2002

(51) Int. Cl. H01L 21/00

(52) U.S. Cl. 430/317; 430/319; 430/321; 438/30; 438/160

(57) ABSTRACT

A method of producing a thin film transistor is described. The doped amorphous silicon is formed by ion implantation. The photoresist used by the ion implantation is formed by backside exposure or by half-tone photo mask, and a photo mask can therefore be eliminated.

### BACKGROUND OF THE INVENTION

1. Field of Invention

The present invention relates to a method of fabricating a thin film transistor liquid crystal display (TFT-LCD). More particularly, the present invention relates to a method of producing a thin film transistor (TFT).

2. Description of Related Art

Liquid crystal display (LCD) has many advantages over other conventional types of displays including high display quality, small volume occupation, lightweight, low voltage driven and low power consumption. Hence, LCDs are widely used in small portable televisions, mobile telephones, video recording units, notebook computers, desktop monitors, projector televisions and so on. Therefore, LCDs have gradually replaced the conventional cathode ray tube (CRT) as a mainstream display unit. In particular, the market is mainly occupied by the TFT-LCD due to the high display quality and the low consumption power of the TFT-LCD. The doped amorphous silicon layer of a thin film transistor in TFT-LCD is formed either by ion implantation after depositing the amorphous silicon layer or by in situ doping with dopant during deposition of the amorphous silicon layer. Since the TFT needs an undoped amorphous silicon layer to be a channel between a source and a drain for charge carriers, a photo mask is needed to help to define the doped and undoped regions.

FIG. 1 is a schematic, cross-sectional view of forming source/drains of a thin film transistor in a conventional top gate design by implanting ions. In FIG. 1, a silicon island, composed of source/drains 105 and a channel 110, has been formed on a transparent substrate 100. A gate dielectric layer 115, a gate 120 and a photoresist layer 130 have also been formed on the silicon island. The method of forming the source/drains 105 is ion implantation, and the photoresist layer 130 and the gate 120 are used as an implanting mask. The implant energy of these implanted ions 140 is quite high because these ions 140 need to penetrate the gate dielectric layer 115 to reach the silicon island exposed by the gate 120. Therefore, the surface of the photoresist 130 is easily coked, and the coked photoresist layer 130 is very hard to remove completely. In addition, the cost of an ion implantor is quite high; hence the production cost is hard to reduce.

FIG. 2 is a schematic, cross-sectional view of forming source/drains of a thin film transistor by implanting ions, which is disclosed in U.S. Pat. No. 6,429,456 owned by Semiconductor Energy Laboratory. In FIG. 2, a gate 205, a gate oxide layer 210, a gate dielectric layer 215 and a silicon island, composed of source/drains 220 and a channel 225, have been formed on a transparent substrate 200. A silicon nitride layer is formed and then is patterned to form a mask layer 230 on the channel 225 by using the photoresist layer 235 as an etching mask. Next, ions are implanted into the silicon island, exposed by the photoresist layer 235 and the mask layer 230, to form source/drains 220. Although this method avoids implanting high-energy ions, one more photo mask is needed to define the mask layer 230 and the production cost and time are thus increased.

FIGS. 3A-3B are schematic, cross-sectional view of forming source/drains of a thin film transistor by oxidizing or nitriding a doped amorphous silicon in U.S. Pat. No. 6,429,456 owned by NEC Corp. In FIG. 3A, a gate 305, a gate dielectric layer 310, an undoped amorphous silicon layer 320 and a doped amorphous silicon layer have been sequentially formed on a transparent substrate 300. Metal source/drains 340 are then formed on the regions of the source/drain. The metal source/drains 340 are used as a mask to oxidize or nitrify the doped amorphous silicon layer by oxygen-containing or nitrogen-containing plasma to form insulating layers 330. At the same time, source/drains 335 are also defined in the doped amorphous silicon layer. In FIG. 3B, the insulating layers 330 outside the metal source/drains 340 are removed by acid solution. Then, the undoped amorphous silicon layer 320 is etched to form a channel 320a and to accomplish the island-like structure of TFT.

This method utilizes the difference in materials of the insulating layers 330 and the undoped amorphous silicon layer 320 to remove the insulating layers 330 selectively. The surface of the undoped amorphous silicon layer 320, serving as a channel, avoids damage during the period of patterning the source/drains 335 as seen in conventional methods, and thus the electrical property of TFT is unaffected. However, the metal source/drains 340 are not patterned by a self-aligned method. An alignment error of the metal source/drains 340 with the gate 305 can occur to produce problems of parasitic capacitance resulting from overlapping the metal source/drains 340 and the gate 305.

### SUMMARY OF THE INVENTION

It is therefore an objective of the present invention to provide a method of producing a thin film transistor to eliminate a photo mask and reduce the production cost and time.

It is another an objective of the present invention to provide a method of producing a thin film transistor to reduce the overlap regions of the second metal layer and the first metal layer and thus reduce the parasitic capacitance.

It is still another an objective of the present invention to provide a method of producing a thin film transistor to reduce the thickness of the amorphous silicon layer and thus reduce the photo current.

In accordance with the foregoing and other objectives of the present invention, a method of producing thin film transistor is provided. This method comprises the following steps. A first metal layer is formed on a transparent substrate and then is patterned to form a gate on the transparent substrate. A gate dielectric layer and an amorphous silicon layer are sequentially formed on the transparent substrate. The amorphous silicon layer is patterned to form a silicon island on the gate dielectric layer over the gate. A photoresist layer is formed and then is patterned by backside exposure to form a photoresist mask on the central part of the silicon island. The silicon island exposed by the photoresist mask is implanted by ions to form a source and a drain over two sides of the gate, and the photoresist mask is then removed.

In accordance with the foregoing and other objectives of the present invention, another method of producing a thin film transistor is provided. This method comprises the following steps. A first metal layer is formed on a transparent substrate and then is patterned to form a gate on the transparent substrate. A gate dielectric layer and an amorphous silicon layer are sequentially formed on the transparent substrate. A photoresist layer is formed on the amorphous silicon layer and then is exposed by a half-tone photo mask. Next, the photoresist layer is developed to form a first photoresist mask on the amorphous silicon layer over the gate, and the thickness of the first photoresist mask on the gate is larger than that of the first photoresist mask on the two sides of the gate. The amorphous silicon layer exposed by the first photoresist mask is etched to form a silicon island on the gate dielectric layer over the gate. Then, the first photoresist mask is vertically etched to expose the silicon island on the two sides of the gate to form a second photoresist mask on the gate. The silicon island exposed by the second photoresist mask is implanted by ions to form a source and a drain over two sides of the gate, and the second photoresist mask is then removed.

In the foregoing, the invention allows backside exposure or half-tone photo mask to be used in the exposure step, and hence at least one photo mask is eliminated. Since the cost of producing a photo mask is expensive and the time used for photolithography is long, eliminating a photo mask needed can save lots of production cost and time. Furthermore, eliminating a photo mask can decrease the alignment error and thus increase the product quality.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic, cross-sectional view of forming source/drains of a thin film transistor in a conventional top gate design by implanting ions;

FIG. 2 is a schematic, cross-sectional view of forming source/drains of a thin film transistor by implanting ions, which is disclosed in U.S. Pat. No. 6,437,366 owned by Semiconductor Energy Laboratory;

FIGS. 3A-3B are schematic, cross-sectional views of forming source/drains of a thin film transistor by oxidizing or nitriding a doped amorphous silicon in U.S. Pat. No. 6,429,456 owned by NEC Corp.;

FIGS. 4A-4B are schematic, cross-sectional views showing a process of producing a thin film transistor according to one preferred embodiment of this invention;

FIGS. 5A-5B are schematic, cross-sectional views showing a process of producing a thin film transistor according to another preferred embodiment of this invention;

FIG. 6 is a schematic, cross-sectional view showing a subsequent process after FIGS. 4A-4B or 5A-5B to finish producing a thin film transistor array plate; and

FIG. 7 is a schematic, cross-sectional view showing another subsequent process after FIGS. 4A-4B or 5A-5B to finish producing a thin film transistor array plate.

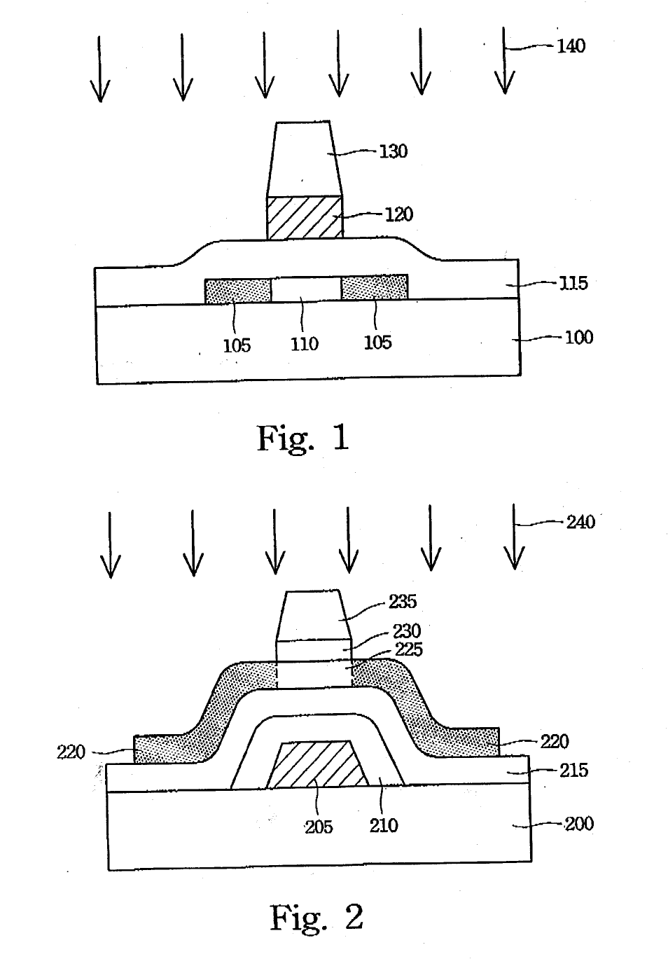

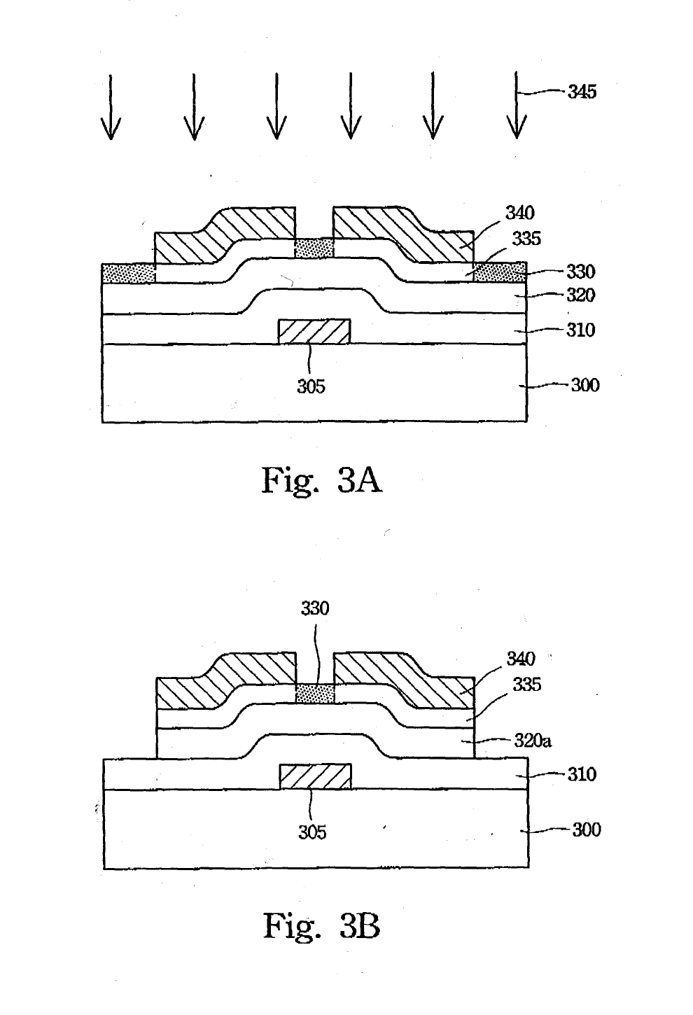

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

As described above, this invention provides a method of producing a thin film transistor, which method is applied in producing liquid crystal display. A backside exposure or a half-tone photo mask is used in the exposure step, and hence at least one photo mask is eliminated. Therefore, lots of production cost and time are saved, and the product quality is increased.

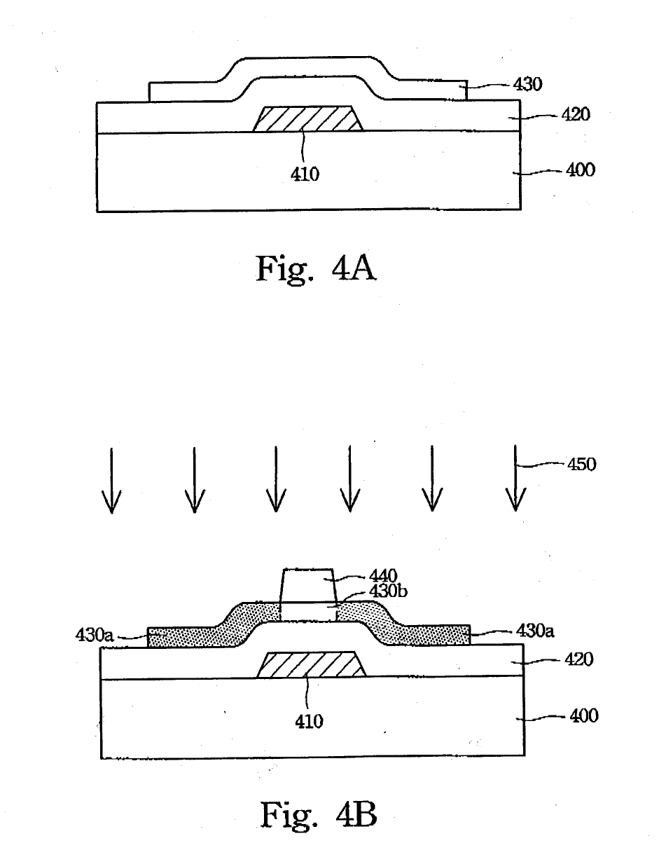

FIGS. 4A-4B are schematic, cross-sectional views showing a process of producing a thin film transistor according to one preferred embodiment of this invention. In FIG. 4A, a first metal layer is formed on a transparent substrate 400 and then is patterned to form a gate 410 on the transparent substrate 400. Next, a gate dielectric layer 420 and an amorphous silicon layer are sequentially formed on the transparent substrate 400. The amorphous silicon layer is patterned to form a silicon island 430 on the gate dielectric layer 420 over the gate 410. The material of the first metal layer is, for example, copper, aluminum, chromium or alloy of molybdenum and tungsten, and the first metal layer is formed by, for example, a physical vapor deposition process such as sputtering.

In FIG. 4B, a photoresist layer is formed and then is patterned by backside exposure to form a photoresist mask 440 on the central part of the silicon island 430. Backside exposure is an exposure method that takes advantage of the opaque feature of the gate 410 and uses the same as a photo mask to expose the photoresist layer from the bottom side of the transparent substrate 400. Then, the silicon island 430 exposed by the photoresist mask 440 is implanted with ions 450 to form source/drains 430a over two sides of the gate 410, and thus a channel 430b between the two source/drains 430a is formed. The method of implanting ions 450 into the exposed silicon island 430 is, for example, ion implantation by an implantor, ion doping by an ion doper, or plasma doping by a plasma-enhanced chemical vapor deposition reactor.

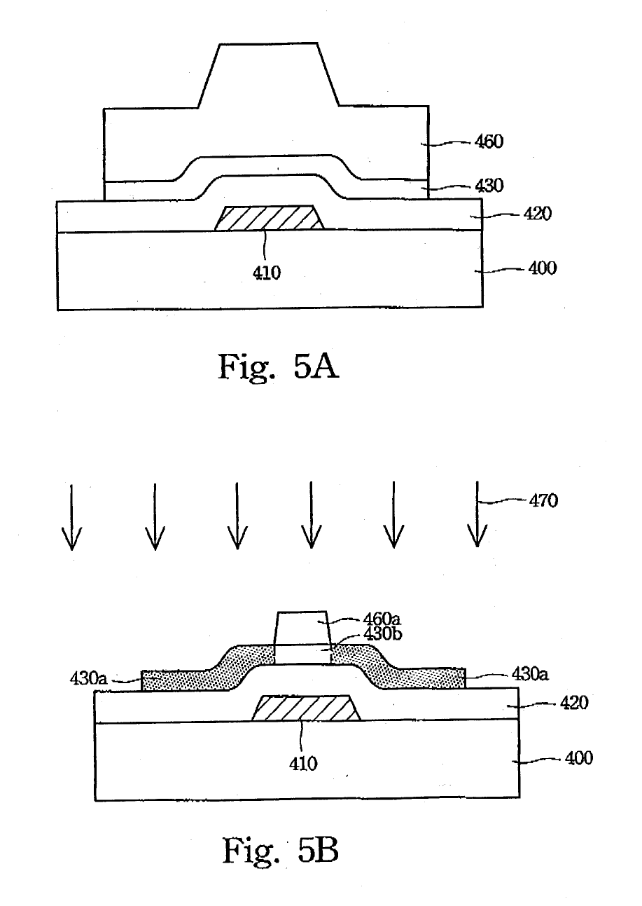

FIGS. 5A-5B are schematic, cross-sectional views showing a process of producing a thin film transistor according to another preferred embodiment of this invention. In FIG. 5A, a first metal layer is formed on a transparent substrate 400 and then is patterned to form a gate 410 on the transparent substrate 400. The material of the first metal layer is, for example, copper, aluminum, chromium or alloy of molybdenum and tungsten. The first metal layer is formed by, for example, a physical vapor deposition process such as sputtering.

A gate dielectric layer 420 and an amorphous silicon layer are sequentially formed on the transparent substrate 400. Then, a photoresist layer is formed on the amorphous silicon layer and is subsequently exposed by a half-tone photo mask. Next, the photoresist layer is developed to form a first photoresist mask 460 on the amorphous silicon layer over the gate 410.

Light transmission rate of some regions on a half-tone photo mask is reduced to reduce the exposure intensity of the corresponding regions of the photoresist layer. Therefore, a photoresist layer with various thickness, such as the first photoresist mask 460 in FIG. 5A, is formed. In FIG. 5A, the thickness of the first photoresist mask 460 on the gate 410 is larger than that of the first photoresist mask 460 above the two sides of the gate 410. For the shape of the first photoresist mask 460, the exposure intensity is zero on the central part of the photoresist layer and larger than zero but lower than normal on both sides of the central part if the material of the photoresist layer is a positive type photoresist. Since the exposure intensity is lower than normal, the photoresist layer with a partial thickness is left.

In FIG. 5B, the first photoresist mask 460 is vertically etched to expose the silicon island 430 above the two sides of the gate 410 to form a second photoresist mask 460a above the gate 410. The silicon island 430 exposed by the second photoresist mask 460a is implanted by ions 470 to form two source/drains above the two sides of the gate 410, and thus a channel 430b between the two source/drains 430a is formed. The method of implanting ions 470 into the exposed silicon island 430 is, for example, ion implantation by an implantor, ion doping by an ion doper, or plasma doping by a plasma-enhanced chemical vapor deposition reactor.

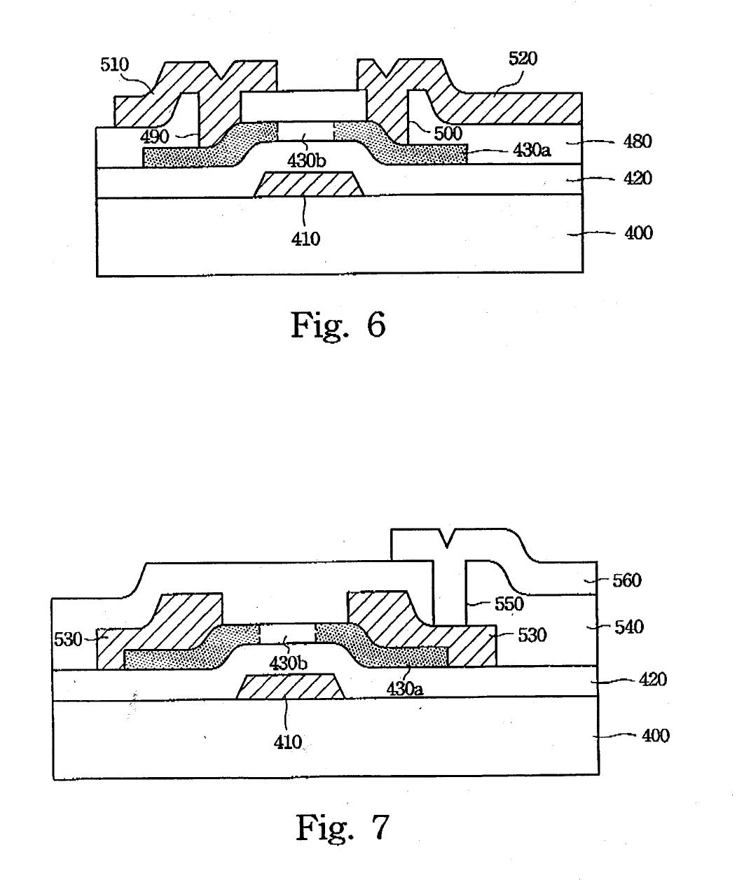

FIG. 6 is a schematic, cross-sectional view showing a subsequent process after FIGS. 4A-4B or 5A-5B to finish producing a thin film transistor array plat of a reflective liquid crystal display. In FIG. 6, the photoresist mask 440 or the second photoresist mask 460a is removed. Then, the ions doped in the source/drains 430a are activated by rapid thermal annealing. A passivation layer 480 is formed over the transparent substrate 400 and then is patterned to form a first contact hole 490 and a second contact hole 500 to expose the source/drains 430a, respectively. The passivation layer 480 is formed by chemical vapor deposition, and its material is silicon nitride.

Next, a second metal layer is formed on the passivation layer 480 and in the first and the second contact holes 490 and 500. The second metal layer is patterned to form a data line 510 and a pixel electrode 520. The data line 510 electrically connects to the source/drain 430a on the left side through the first contact hole 490, and the pixel electrode 520 electrically connects to the source/drain 430a on the right side through the second contact hole 500. The material of the second metal layer is, for example, copper, aluminum, chromium or alloy of molybdenum and tungsten, and the first metal layer is formed by, for example, a physical vapor deposition process such as sputtering.

FIG. 7 is a schematic, cross-sectional view showing another subsequent process after FIGS. 4A-4B or 5A-5B to finish producing a thin film transistor array substrate of a transmissive liquid crystal display. In FIG. 7, the photoresist mask 440 or the second photoresist mask 460a is removed. Then, the ions doped in the source/drains 430a are activated by rapid thermal annealing. A second metal layer is formed over the transparent substrate 400 and then is patterned to form two metal source/drains 530 respectively on the two source/drains 430a. The material of the second metal layer is, for example, copper, aluminum, chromium or alloy of molybdenum and tungsten, and the first metal layer is formed by, for example, a physical vapor deposition process such as sputtering.

Next, a passivation layer 540 is formed over the transparent substrate 400 and then is patterned to form a contact hole 550 to expose the metal source/drain 530 on the right side. A transparent conductive layer is formed on the passivation layer 540 and in the contact hole 550. The transparent conductive layer is patterned to form a pixel electrode 560 connecting to the metal source/drain 530 on the right side through the contact hole 550 electrically. The passivation layer 540 is formed by a chemical vapor deposition process, and its material is silicon nitride. The material of the above-mentioned transparent conductive layer is, for example, indium tin oxide or indium zinc oxide, and the transparent conductive layer is formed by, for example, physical vapor deposition process such as reactive sputtering.

As described above, the advantages of applying this invention comprises the following advantages:

1. This invention utilizes backside exposure or a half-tone photo mask to expose the photoresist, and a photo mask can thus be eliminated. Since the cost of producing a photo mask is expensive and the time used for photolithography is long, eliminating a photo mask needed can save lots of production cost and time. Furthermore, eliminating a photo mask can decrease the alignment error and thus increase the product quality.

2. The channel length is determined by the gate in the backside exposure process to obtain a more symmetrical source and drain. Moreover, the width of the gate is decreased to increase the aperture ratio of a liquid crystal display.

3. The overlap regions of the data line and the pixel electrode in a reflective LCD or the metal source/drains in the transmissive LCOD with the gate are reduced to zero. Thus, the parasitic capacitance is reduced to the lowest value to decrease current leakage.

4. Since only an etching step and an ion-implanting step is needed to accomplish a coplanar structure of the doped and undoped amorphous silicon layer, the thickness of the amorphous silicon layer is decreased. Therefore, not only can the production yield be increased but also the photocurrent of the thin film transistor is decreased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of producing a thin film transistor for applying to a liquid crystal display, comprising the steps of:
forming a first metal layer on a transparent substrate;
patterning the first metal layer to form a gate on the transparent substrate;
forming a gate dielectric layer on the transparent substrate;
forming an amorphous silicon layer on the gate dielectric layer;
patterning the amorphous silicon layer to form a silicon island on the gate dielectric layer over the gate;
forming a photoresist layer over the transparent substrate;
patterning the photoresist layer by backside exposure to form a photoresist mask on a central part of the silicon island;
implanting ions into the silicon island exposed by the photoresist mask to form a source and a drain over two sides of the gate; and
removing the photoresist mask.

2. The method of claim 1, wherein the step of implanting ions comprises ion implantation, ions doping, or plasma doping.

3. The method of claim 1, wherein a material of the first metal layer comprises copper, aluminum, chromium or alloy of molybdenum and tungsten.

4. The method of claim 1, further comprising a step of rapid thermal annealing after the step of removing the photoresist mask to activate the implanted ions in the source and the drain.

5. The method of claim 1, further comprising steps as follows after the step of removing the photoresist mask:
forming a passivation layer over the transparent substrate;
patterning the passivation layer to form a first contact hole and a second contact hole to expose the source and the drain, respectively;
forming a second metal layer on the passivation layer and in the first contact hole and the second contact hole; and
patterning the second metal layer to form a data line connecting electrically to the source through the first contact hole and a pixel electrode connecting electrically to the drain through the second contact hole.

6. The method of claim 5, wherein the passivation layer comprises a silicon nitride layer.

7. The method of claim 5, wherein a material of the second metal layer comprises copper, aluminum, chromium or alloy of molybdenum and tungsten.

8. The method of claim 1, further comprising steps as follows after the step of removing the photoresist mask:
forming a second metal layer over the transparent substrate;
patterning the second metal layer to form a metal source and a metal drain respectively on the source and the drain;
forming a passivation layer over the transparent substrate;
patterning the passivation layer to form a contact hole to expose the metal drain;
forming a transparent conductive layer on the passivation layer and in the contact hole; and
patterning the transparent conductive layer to form a pixel electrode connecting electrically to the metal drain through the contact hole.

9. The method of claim 8, wherein a material of the second metal layer comprises copper, aluminum, chromium or alloy of molybdenum and tungsten.

10. The method of claim 8, wherein the passivation layer comprises a silicon nitride layer.

11. The method of claim 8, wherein the transparent conductive layer comprises an indium tin oxide layer or an indium zinc oxide layer.

12. A method of producing a thin film transistor for applying to a liquid crystal display, comprising the steps of:
forming a first metal layer on a transparent substrate;
patterning the first metal layer to form a gate on the transparent substrate;
forming a gate dielectric layer on the transparent substrate;
forming an amorphous silicon layer on the gate dielectric layer;
forming a photoresist layer on the amorphous silicon layer;
exposing the photoresist layer by a half-tone photo mask;
developing the photoresist layer to form a first photoresist mask on the amorphous silicon layer over the gate, wherein a first thickness of the first photoresist mask on the gate is larger than a second thickness of the first photoresist mask on two sides of the gate;
etching the amorphous silicon layer exposed by the first photoresist mask to form a silicon island on the gate dielectric layer over the gate;
vertically etching the first photoresist mask to expose the silicon island on two sides of the gate to form a second photoresist mask on the gate;
implanting ions into the silicon island exposed by the second photoresist mask to form a source and a drain over the two sides of the gate; and
removing the second photoresist mask.

13. The method of claim 12, wherein the step of implanting ions comprises ion implantation, ions doping, or plasma doping.

14. The method of claim 12, wherein a material of the first metal layer comprises copper, aluminum, chromium or alloy of molybdenum and tungsten.

15. The method of claim 12, further comprising a step of rapid thermal annealing after the step of removing the second photoresist mask to activate the implanted ions in the source and the drain.

16. The method of claim 12, further comprising steps as follows after the step of removing the second photoresist mask:
forming a passivation layer over the transparent substrate;
patterning the passivation layer to form a first contact hole and a second contact hole to expose the source and the drain, respectively;
forming a second metal layer on the passivation layer and in the first contact hole and the second contact hole; and
patterning the second metal layer to form a data line connecting electrically to the source through the first contact hole and a pixel electrode connecting electrically to the drain through the second contact hole.

17. The method of claim 16, wherein the passivation layer comprises a silicon nitride layer.

18. The method of claim 16, wherein a material of the second metal layer comprises copper, aluminum, chromium or alloy of molybdenum and tungsten.

19. The method of claim 12, further comprising steps as follows after the step of removing the second photoresist mask:
forming a second metal layer over the transparent substrate;
patterning the second metal layer to form a metal source and a metal drain respectively on the source and the drain;
forming a passivation layer over the transparent substrate;
patterning the passivation layer to form a contact hole to expose the metal drain;
forming a transparent conductive layer on the passivation layer and in the contact hole; and
patterning the transparent conductive layer to form a pixel electrode connecting electrically to the metal drain through the contact hole.

20. The method of claim 19, wherein a material of the second metal layer comprises copper, aluminum, chromium or alloy of molybdenum and tungsten.

21. The method of claim 19, wherein the passivation layer comprises a silicon nitride layer.

22. The method of claim 19, wherein the transparent conductive layer comprises an indium tin oxide layer or an indium zinc oxide layer.
